(19) United States
(12) Patent Application Publication
(10) Pub. No.: US 2025/0147088 A1
(43) Pub. Date: May 8, 2025

(54) GENERAL METHOD FOR ELIMINATING COMMON MODE INTERFERENCES IN BOTH ELECTRIC AND MAGNETIC SIGNAL MEASUREMENT SYSTEMS

(71) Applicant: MAISONBURG(SHENZHEN)TECHNOLOGY DEVELOPMENT CO., LTD., Shenzhen, Guangdong (CN)

(72) Inventor: Tongsheng ZHANG, Shenzhen, Guangdong (CN)

(21) Appl. No.: 18/835,504

(22) PCT Filed: Dec. 23, 2022
(86) PCT No.: PCT/CN2022/141628

§ 371 Date: Aug. 2, 2024

Related U.S. Application Data
(60) Provisional application No. 63/293,141, filed on Dec. 23, 2021.

(51) Int. Cl. G01R 29/08; G01R 33/00

(52) U.S. Cl. CPC G01R 29/0892; G01R 33/0023

(57) ABSTRACT

A novel general method for eliminating interference in both electrical and magnetic measurement systems is disclosed in this invention. The method applies to both electro and magnetic measurements using differential amplifiers, wherein the common-mode signal is extracted to serve as an interference template after being amplified and digitally sampled along with the differential signals. The method involves identifying matching template components within the signal and subtracting them to eliminate interference and improve the signal-to-noise ratio. For magnetic signal detection sensors using gradient coil structures, the symmetric point is grounded so that the mixed signal which contains the common-mode components representing interference and measurement signal are output at the two signal terminals. Similar to electrical measurements, the common-mode components_are_extracted from differential amplifier as an interference template, followed by template matching analysis as mentioned above and subtraction to remove interference components from the signal.

### CROSS-REFERENCE TO RELATED APPLICATION

This application is a 35 U.S.C. § 371 national stage application of PCT patent application No. PCT/CN2022/141628, filed on Dec. 23, 2022, which claims priority to U.S. provisional patent application No. 63/293,141 filed on Dec. 23, 2021, and entitled “method and apparatus for filtering interference in detection of electric and magnetic signals”, the entire contents each of which are incorporated herein by reference.

### TECHNICAL FIELD

This application relates to the technical field of electrical and magnetic interference suppression in the measurement of electrical and magnetic signals, and more specifically, to a general method for eliminating electrical and magnetic interference in measurement systems.

### BACKGROUND

The measurement and analysis of electrical and magnetic signals are essential components in everything from scientific research to almost all application fields. One of the most critical indicators of the performance of electro and magnetic measurement systems is the signal-to-noise ratio (SNR). Given a measurement signal, reducing noise is a key factor in improving the SNR. Generally, noise originates from two main sources: first, the noise from the signal source and the measurement circuit itself, particularly the thermal noise due to the random drift of electrons in the measurement circuit related to ambient temperature; second, interference components from other external electrical and magnetic signal sources. The method invented in this application is aimed at suppressing the interference components in the signal, also known as interference signals, which can be electrical components or induced electrical components from external magnetic field changes in the measurement system. In this discussion, noise and interference might be used interchangeably, and unless otherwise specified, noise refers specifically to interference. Magnetic signals refer to signals where the magnetic induction amplitude changes over time, such as the magnetic resonance signals detected by nuclear magnetic resonance instruments, or the magnetic signals measured by magnetoencephalography instruments accompanying neural discharge activities.

Typically, to deal with electrical interference in electrical measurements, a basic method taught in textbooks is to use a bipolar electrode configuration for electrical measurements. The detected signal is fed to a preamplifier circuit composed of a differential amplifier (or instrumentation amplifier) with a high common-mode rejection ratio (CMRR) for amplification. For example, electrocardiograph clinical settings to measure electrocardiographic commonly employ this input method. The reason for this is that the electrodes are often placed closer to the signal source being measured, detecting the potential difference between the two electrodes. External interference, such as power line interference from ubiquitous power lines, originates from a location further away than the distance between the two measurement electrodes. Therefore, the interference voltage induced at the two measurement electrodes is in phase and has the same or similar amplitude, showing obvious common-mode characteristics that can be easily suppressed by a differential amplifier with a high CMRR.

Nonetheless, common-mode interference still exists in the measured electrocardiograph signals. Therefore, standard electrocardiograms always include a selectable 50 Hz (or 60 Hz, depending on the country of use) notch filter for further filtering.

Similar to the electrical measurements mentioned above, all magnetic signal measurement systems are inevitably subject to noise interference. In magnetic signal measurements, to suppress interference, a gradient coil structure measuring probe is commonly used to detect magnetic signals. The most common gradient coil is the figure-8 (fig-of-8) structure. Two circular coils of the same area and winding are placed closely adjacent to each other on the same plane (planar gradient coil) or axially spaced (axial gradient coil), forming a gradient antenna. The magnetic interference signal being measured generates equal and opposite currents in the coil, thus canceling out the common-mode interference. A typical application example of a planar figure-8 gradient antenna is a device that uses the geomagnetic field as a polarizing field to detect underwater oil spills in the Arctic region (L. Chavez et al., “Detecting Arctic oil spills with NMR: a feasibility study,” Near Surface Geophysics 13(4), 409-416(2015)). Such an antenna system can sensitively detect weak geomagnetic nuclear magnetic resonance signals and effectively suppress environmental interference.

Obviously, the symmetry of the gradient antenna determines its ability to suppress common-mode magnetic interference. Common figure-of-8 and various deformed symmetric antennas show axial symmetry in the plane where the antenna is located. The same inventor of this application previously invented a centrally symmetric antenna for measuring quadrupole resonance signals, structurally easier to achieve symmetry, and with better common-mode interference suppression capability (U.S. Pat. No. 11,300,644, Nuclear quadrupole resonance detection system and antenna).

In some applications, to highlight the signal corresponding to one coil of the gradient antenna, an asymmetric structure is often used, where the diameters or the number of turns of the two coils are different. A high-resolution infant brain magnetoencephalography system invented by A. P. Ewing et al. (US20040002645A1 High-Resolution Magnetoencephalography System and Method) uses an asymmetric axial gradient coil structure.

However, since gradient coils are not perfectly symmetrical in manufacturing, and the loop formed by the antenna to input amplifier connection may also induce interfering magnetic signals in magnetic signal measurements, thus, part of the common-mode interference can mix with the differential signal entering the amplification process, reducing the SNR. Therefore, in the measurement circuit, appropriate filters are often designed to further filter out interference based on the frequency characteristics of possible interfering signals.

In multi-channel electrical signal measurement and multi-channel magnetic signal measurement, orthogonal spatial decomposition of signals is often used to distinguish between signals and interference, completing the filtering of interference in signal processing and analysis (US20140128002A1, Method and system for using orthogonal space projections to mitigate interference).

Additionally, in the prior art, Chinese Patent Application Publication No. CN109004911A (charging and discharging device) discloses a differential amplifier with adjustable common-mode suppression and an amplifier circuit with improved common-mode suppression. It achieves this by estimating the common-mode voltage value of the input signal and using the estimated common-mode voltage value to adjust the target common-mode voltage of the amplifier output. Although this method of common-mode suppression reduces common-mode interference in the mixed signal output to some extent and improves the SNR of the output signal, it still cannot effectively reduce or completely eliminate common-mode interference signals mixed in the differential signal.

In summary, various existing anti-interference technologies, from antenna structures to signal processing and analysis, as well as circuit design, have been extensively developed and researched. Currently, there is still a lack of a general solution that can effectively eliminate common-mode interference in the measurement of electrical/magnetic signals and improve the SNR of the output signal.

### SUMMARY

The technical problem this application aims to solve is the interference issues present in current electrical and magnetic signal measurement technologies. These problems are either caused by the electrode positions or lead wires in electrical measurements or by the imperfect symmetry of gradient antennas in magnetic measurements, resulting in part of the common-mode interference mixing with the original desired differential signal, thereby always causing some common-mode interference to be mixed in the output signal, affecting the signal-to-noise ratio. This application provides a general method for eliminating electrical and magnetic interference in measurement systems, which can eliminate common-mode interference signals mixed in the differential signal, thereby obtaining the original desired signal with a high signal-to-noise ratio, effectively solving the technical problem of unavoidable common-mode noise pollution in electrical and magnetic signal measurements.

The technical solutions adopted in the present application to solve the above technical problems are set forth below:

A general method for eliminating electrical and magnetic interference in measurement systems is provided, this method includes the following steps:
in magnetic signal measurement, grounding the center symmetry point of the measuring gradient antenna, and outputting the magnetic induction differential signal from both ends of the gradient antenna; or in electrical signal measurement, outputting differential signals through bipolar pickup electrodes;
outputting both differential and common mode signals from a differential amplifier (i.e., a preamplifier);
amplifying and sampling the differential and common model signals;
using the sampled common-mode signal as an interference noise template, and identifying common-mode interference components corresponding to the interference noise template from the differential signal; and
removing the common-mode interference components from the differential signal to obtain an original desired signal with a high signal-to-noise ratio from which the common-mode interference components have been removed.

Further, the step of outputting both differential and common mode signals from the differential amplifier includes:
outputting a mixed signal through the preamplifier; a mathematic model of the mixed signal is: Sₘᵢₓ(t)=Sᵢ(t)+S_{c}(t)+Nᵢ(t), where Sᵢ(t) represents desired differential signal component, S_{c}(t) represents the common-mode interference components mixed in the mixed signal Sₘᵢₓ(t), while Nᵢ(t) is inherent white noise;
outputting the total common-mode signal through the preamplifier; a mathematic expression of the total common-mode signal is: Sₚ(t)=S_{C}(t)+N_{C}(t), where S_{C}(t) represents the common-mode interference component output from the preamplifier, while N_{C}(t) represents the white noise mixed with the common-mode interference component. Note the difference S_{C}(t) (capital C) in common mode signal and S_{c}(t) (lower case c) in mixed signal Sₘᵢₓ(t).

The common-mode interference component S_{c}(t) in the differential signal and the common-mode interference component S_{C}(t) are originated from the same interference sources, Thus the common-mode interference component S_{c}(t) and the common-mode interference component S_{C}(t) satisfy a linear relationship which is expressed as:

$${S}_{c} ( t ) = k * {S}_{C} ( t ) ;$$

Where, the coefficient k satisfies the following condition:
Sᵢ-Minimizing_{k→Var} {Sₘᵢₓ(t)−k·Sₚ(t)}, Sₚ(t) is S_{C}(t) mixed with a white noise N_{C}(t) in common mode channel. Since S_{C}(t) dominates Sₚ(t), for facilitating understanding, S_{C}(t) is frequently used instead of Sₚ(t) in the context of this application. A physical meaning of the above mathematical optimization variance expression is that the common-mode interference component S_{c}(t) in the differential signal is a proportionate scaling of the common-mode interference component S_{C}(t). Typically, since S_{C}(t)>S_{c}(t), k is often less than 1;

The step of outputting both differential and common mode signals from the differential amplifier further includes:
determining the coefficient k according to the above condition, and determining the common-mode interference component S_{c}(t) in the signal according to the coefficient k, where the common-mode interference component S_{C}(t) serves as the interference noise template.

Further, the step of removing the common-mode interference component from the differential signal specifically includes:
identifying the common-mode interference component in the mixed signal corresponding to the total common-mode output and then removing the common-mode interference component from the mixed signal to obtain the original desired signal.

Further, the method further includes:
filtering and amplifying the differential signal transmitted in a signal channel, converting the differential signal into a first digital signal, and then storing the digital signal in a first memory or outputting the digital signal to a first MCU, to analyze and process the digital signal through the first MCU;
performing the same filtering and amplifying processing on the common-mode signal transmitted in a common-mode channel as in the differential channel, converting the common-mode signal into a second digital signal, and then storing the second digital signal in a second memory or outputting the second digital signal to a second MCU, to analyze and process the second digital signal through the second MCU.

The general method for eliminating electrical and magnetic interference in measurement systems proposed in this application has at least the following beneficial effects:

First, according to the general method for eliminating electrical and magnetic interference in measurement systems proposed in the present application, the common-mode signal output from the preamplifier can be used as an interference noise template, the common-mode interference component corresponding to the interference noise template is identified in the output mixed signal, and then the common-mode interference component is then removed from the mixed signal to obtain the original desired signal with a high signal-to-noise ratio, from which the common-mode interference has been eliminated. Therefore, it perfectly solves the technical problem of inevitable interference to the original desired signal due to partial common-mode signal becoming differential signal and mixing with the original desired signal, which is caused by incomplete symmetry in electrical and magnetic signal measurements.

Second, since the realization principle of magnetic common-mode interference elimination proposed in this application is to extract the common-mode signal from the differential measurement of the magnetic signal, use this common-mode signal to establish an interference noise template, and use the interference noise template to identify the corresponding common-mode interference component in the mixed signal, and then remove the common-mode interference component from the mixed signal to obtain the original desired signal with a high signal-to-noise ratio, it is only necessary to ground the center symmetric point of the gradient coil to provide a differential signal to the preamplifier without the need for adding a large number of additional electronic components. This makes the circuit structure of the common-mode interference elimination circuit proposed in the present application extremely simple, low cost, and effective in eliminating common-mode interference, with high application value and broad prospects.

### DESCRIPTION OF THE DRAWINGS

Below, the general method for eliminating electrical and magnetic interference in measurement systems is explained with reference to the drawings and specific embodiments.

FIG. 1 is a flowchart of a preferred embodiment of the general method for eliminating electrical and magnetic interference in measurement systems provided by this application;

FIG. 2 is a specific implementation flowchart of the step of extracting common-mode signals from differential signals included in the general method for eliminating electrical and magnetic interference in measurement systems shown in FIG. 1;

FIG. 3 is an optimization processing scheme of differential and common-mode signals included in the method for eliminating common-mode interference shown in FIG. 1;

FIG. 4 is a schematic circuit configuration of the first common-mode interference elimination circuit provided by a preferred embodiment of this application, where the common-mode signal representing interference is output in a traditional differential amplifier;

FIG. 5 is a schematic circuit configuration of the second common-mode interference elimination circuit provided by a preferred embodiment of this application, designed to suppress interference for measuring magnetic signals using gradient antennas.

### DETAILED DESCRIPTION OF EMBODIMENTS

In order to make the objectives, the technical solutions, and the technical effects of the present application be clearer, the following is a detailed description of the general method for eliminating electrical and magnetic interferences in measurement systems with reference to the accompanying drawings and specific implementation methods. It should be understood that the specific implementation methods described in this specification are only for explaining the present application rather than limiting the present application.

To solve the technical problem in the prior art where, in the measurement of electrical and magnetic signals, some common-mode signals become differential signals and mix with the original desired signal due to the imperfect symmetrical measurement input circuit, inevitably causing interference to the original desired signal, the innovations of this application are as follows:

First, based on the fact that the interference in the mixed signal transmitted in a signal channel and the common-mode signal representing interference transmitted in a common-mode channel are both originated from the same interference source and have a specific linear relationship (i.e., the difference between these two common-mode signals is reflected in their respective amplitudes, rather than their waveform characteristics), the common-mode signal output from the preamplifier (PreAMP) is used as the noise template for interference. The common-mode interference component corresponding to this noise template is identified in the mixed signal and then removed from the latter, thereby obtaining the original desired signal with a high signal-to-noise ratio, from which the common-mode interference has been eliminated.

Second, since the implementation principle of eliminating magnetic common-mode interference proposed in this application is to extract the common-mode signal from the differential measurement of the magnetic signal that establishes a common-mode interference noise template, and use this interference template to identify the corresponding common-mode interference component in the mixed signal, and then remove this common-mode interference component from the mixed signal to obtain the original desired signal with a high signal-to-noise ratio, it is only necessary to ground the center symmetry point of the gradient coil to provide a differential signal to the preamplifier and output a common-mode signal from it, without the need for a large number of additional electronic components. This makes the circuit structure of the common-mode interference elimination circuit proposed in this application extremely simple. Thus, the circuit structure has a low-cost, and is highly effective in eliminating common-mode interference.

The following is a detailed description of the general method for eliminating electrical and magnetic interferences in measurement systems according to this application with reference to the accompanying drawings and specific embodiments:

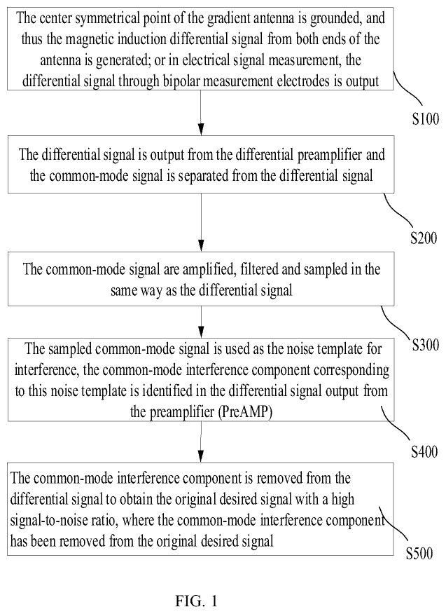

As shown in FIG. 1, since the gradient coil cannot be made completely ideally symmetrical in practice, in order to overcome the technical bottleneck that magnetic signal measurement inevitably suffers from common-mode interference, this application proposes a general method for eliminating electrical and magnetic interference in measurement systems, which specifically includes the following steps:

At step S100, the center symmetrical point of the gradient antenna is grounded, and thus the magnetic induction differential signal from both ends of the antenna is generated; or in electrical signal measurement, the differential signal through bipolar measurement electrodes is output.

At step S200, the differential signal is output from the differential preamplifier and the common-mode signal is separately output from the differential preamplifier.

At step S300, the common-mode signal are amplified, filtered and sampled in the same way as the differential signal.

At step S400, the sampled common-mode signal is used as the noise template for interference, the common-mode interference component corresponding to this noise template is identified in the differential signal output from the preamplifier (PreAMP), that is amplified and sampled in the same way as the common mode interference; and

At step S500, the common-mode interference component is removed from the differential signal to obtain the original desired signal with a high signal-to-noise ratio, where the common-mode interference component has been removed from the mixed signal.

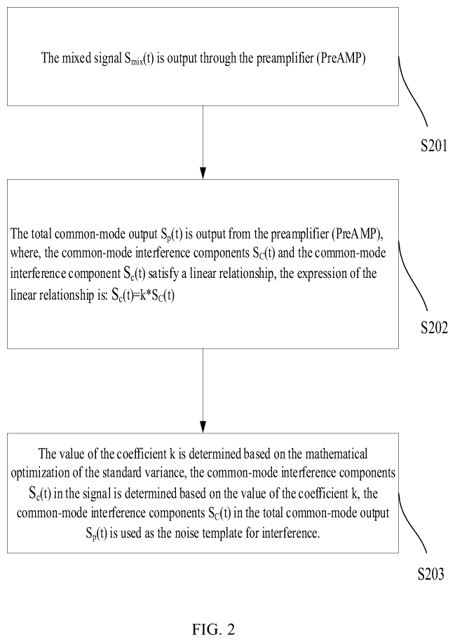

As shown in FIG. 2, in a preferred implementation, the above step S200 specifically includes:

At step S201, the mixed signal Sₘᵢₓ(t) is output through the preamplifier (PreAMP); an expression of this mixed signal Sₘᵢₓ(t) is: Sₘᵢₓ(t)=Sᵢ(t)+S_{c}(t)+Nᵢ(t) (i.e., Formula 1).

Where Sᵢ(t) represents the desired differential signal component, S_{c}(t) represents the common-mode interference components mixed in the mixed signal Sₘᵢₓ(t), and Nᵢ(t) represents inherent white noise.

At step S202, the total common-mode output Sₚ(t) from the preamplifier (PreAMP); the expression of this total common-mode output Sₚ(t) is: Sₚ(t)=S_{C}(t)+N_{C}(t) (i.e., Formula 2). Where, S_{C}(t) represents the common-mode interference components output from the preamplifier (PreAMP), and N_{C}(t) represents the white noise mixed with the common-mode interference components S_{C}(t).

The common-mode interference components S_{c}(t) in the differential signal and the common-mode interference components S_{C}(t) output from the preamplifier (PreAMP) are originated from the same noise source, and thus the common-mode interference components S_{C}(t) and the common-mode interference component S_{c}(t) satisfy a linear relationship, the expression of the linear relationship is:

$${S}_{c} ( t ) = k \cdot {S}_{C} ( t ) . \qquad ( i . e . , Formula 3 )$$

From the above formula, it can be seen that the common-mode interference components S_{C}(t) and the common-mode interference components S_{c}(t) in the differential signals are from the same interference source but with different amplitudes.

Based on the above Formulas 1, 2, and 3, the following formula can be derived:

$${S}_{mix} ( t ) = {S}_{i} ( t ) + k \cdot {S}_{p} ( t ) + {N}_{i} ( t ) = {S}_{i} ( t ) + k \cdot {S}_{C} ( t ) + k \cdot {N}_{C} ( t ) + {N}_{i} ( t ) . \qquad ( i . e . , Formula 4 )$$

Since the common-mode interference in the interference source is not related to the desired signal, generally speaking, the common-mode interference is rather orthogonal to the differential signal. Therefore, the coefficient k can be obtained by minimizing the variance of the difference between the mixed signal Sₘᵢₓ(t) and the k proportion of the common-mode signal in the total common-mode output Sₚ(t):

$${S}_{i} = Minimizingk \to Var \{ {S}_{mix} ( t ) - k \cdot {S}_{p} ( t ) \} ; \qquad ( i . e . , Formula 5 )$$

that is, the variance of the difference between the mixed signal Sₘᵢₓ(t) and the total common-mode output Sₚ(t) multiplied by the coefficient k is minimized.

The physical meaning of this mathematical optimization variance expression (i.e., Formula 5) is that the common-mode interference component S_{c}(t) in the differential signal is a scaled proportion of the total common-mode interference S_{C}(t). Usually, since S_{C}(t)>S_{c}(t), the coefficient k is often less than 1. The k value obtained under the condition of Formula 5 minimizes the common-mode components in the obtained signal, which means that the common-mode interference is filtered out.

In this application, the afore said step S200 further includes:

At step S203, the value of the coefficient k is determined based on the mathematical optimization of the standard variance, and the common-mode interference components Sc(t) in the signal is determined based on the value of the coefficient k. Where the common-mode interference components S_{C}(t) is used as the noise template for interference.

In a preferred implementation, the aforesaid step S500 specifically includes:

identifying the common-mode interference components S_{c}(t) corresponding to the total common-mode output Sₚ(t) in the mixed signal Sₘᵢₓ(t), and removing the common-mode interference components S_{c}(t) from the mixed signal Sₘᵢₓ(t) to obtain the original desired signal.

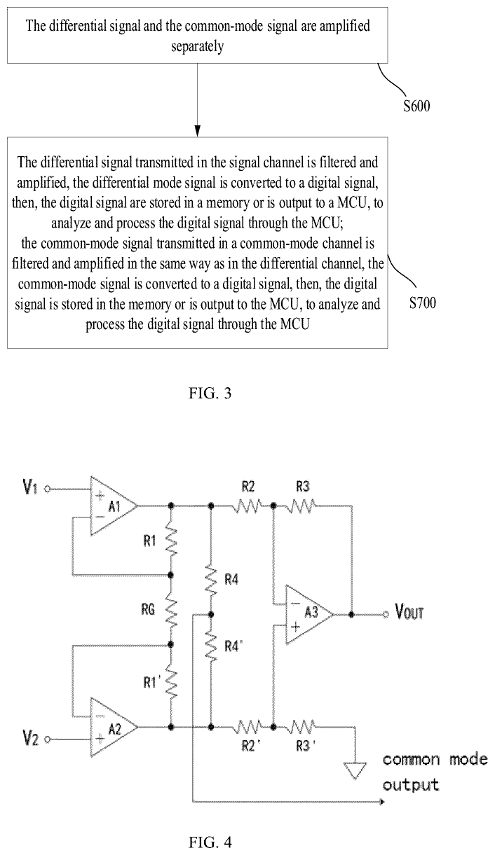

As shown in FIG. 3, in a preferred implementation, the aforesaid method for eliminating common-mode interference further includes:
at step S600, the differential signal and the common-mode signal are amplified separately before the differential signal and the common-mode signal are converted to digital signals.

In a preferred implementation, the aforesaid method for eliminating common-mode interference further includes:

At step S700, the differential signal transmitted in the signal channel are filtered and amplified, the differential signal is converted to a digital signal, then, the digital signal are stored in memory or output to a MCU to analyze and process the digital signal through the MCU;

The common-mode signal transmitted in a common-mode channel are filtered and amplified in the same way as in the differential channel, the common-mode signal is converted to a digital signal. Then, the digital signal is stored in memory or output to the MCU to analyze and process the digital signal through the MCU.

In the present application, the differential signal refers to the signal from bipolar measurement electrodes or the signal from a gradient antenna, with the center symmetry point of the gradient antenna grounded.

In summary, in the general method for eliminating electrical and magnetic interference in measurement systems proposed by the present application, the mixed signal and the common-mode signal can be output through the preamplifier (PreAMP). The common-mode signal output from the preamplifier (PreAMP) is used as the noise template for interference. The common-mode interference component corresponding to this noise template is identified in the mixed signal through the noise template matching method and then removed from the mixed signal, thereby obtaining the original desired signal with a high signal-to-noise ratio, where common-mode interference has been removed from the obtained original desired signal. Therefore, the method for eliminating common-mode interference proposed by the present application can effectively solve the technical problem in electrical and magnetic signal measurement where some common-mode signals become differential signals and mix with the original desired signal due to the imperfect symmetry, thereby inevitably causing interference to the original desired signal.

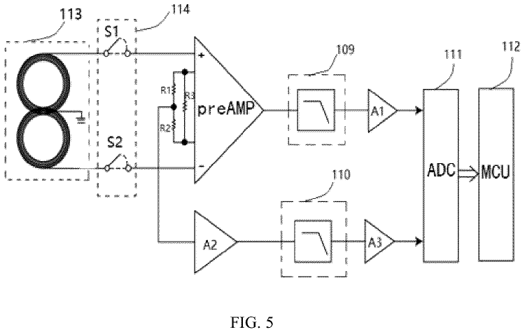

Corresponding to the above general method for eliminating electrical and magnetic interference in measurement systems, as shown in FIG. 4, the present application further discloses a circuit implementation method for outputting a common-mode signal corresponding to interference from a traditional differential amplifier.

As shown in FIG. 5, the present application further discloses a common-mode interference elimination circuit for eliminating magnetic interference in a magnetic signal measurement system. The electronic switch 114 in the circuit is used to isolate the excitation circuit (not shown) from the measurement circuit when the measurement device is used for excitation-response measurement, such as nuclear magnetic resonance or quadrupole resonance signal detection.

In conclusion, the improvements of the present application compared to the prior art are at least reflected in the following aspects:

First, according to the method and device for eliminating common-mode interference proposed in the present application, the common-mode signal output from the preamplifier can be used as the noise template for interference. The common-mode interference component corresponding to this noise template is identified in the output mixed differential signal, and then the common-mode interference component in the mixed differential signal is removed, thereby obtaining the original desired signal with a high signal-to-noise ratio, from which common-mode interference has been removed. This perfectly solves the technical bottleneck in electrical and magnetic signal measurement where some common-mode signals become differential signals and mix with the original desired signal due to the imperfect symmetry, thereby inevitably causing interference to the original desired signal.

Second, since the implementation principle of eliminating magnetic common-mode interference proposed in the present application is to output the common-mode signal from the differential measurement of the magnetic signal, establish a common-mode interference noise template, and use this interference template to identify the corresponding common-mode interference component in the mixed signal, and then remove this common-mode interference component from the mixed signal to obtain the original desired signal with a high signal-to-noise ratio. Thus, it is only necessary to ground the center symmetry point of the gradient coil to provide a differential signal to the preamplifier without the need for a large number of additional electronic components.

This makes the circuit structure of the common-mode interference elimination circuit proposed in the present application extremely simple, low-cost, and highly effective in eliminating common-mode interference, with high application value and broad prospects.

It should be noted that the interference template is affected by the white noise N_{C}(t), which may form a source of interference suppression error.

The above description of the embodiments of the present application with reference to the drawings is illustrative and not restrictive. Those skilled in the art can make many variations based on the inspiration of the present application without departing from the scope and protection of the claims of the present application. Moreover, although specific terms are used in this specification, these terms are for the sake of description, and are not intended to limit the present application.

1. A general method for eliminating electrical and magnetic interference in measurement systems, comprising following steps:
grounding a center-symmetric point of a gradient antenna, and outputting magnetic induction differential signals from both ends of the gradient antenna in magnetic measurements; or in electrical signal measurements, outputting differential signals through bipolar electrodes in electrical signal measurements;
outputting both differential signal and common mode signal from a preamplifier (PreAMP);
amplifying, filtering, and sampling the differential signal and the common mode signal;
using the sampled common-mode signal as an interference noise template, and identifying common-mode interference components corresponding to the interference noise template from the differential signal; and
removing the common-mode interference components from the differential signal to obtain an original desired signal with high signal-to-noise ratio.

2. The general method according to claim 1, wherein the step of outputting both differential signal and common mode signal from the preamplifier (PreAMP) comprises:
outputting a mixed signal Sₘᵢₓ(t) from the preamplifier (PreAMP), an expression of the mixed signal Sₘᵢₓ(t) is: Sₘᵢₓ(t)=Sᵢ(t)+S_{c}(t)+Nᵢ(t), wherein Sᵢ(t) represents an expected differential signal component, S_{c}(t) represents the common-mode interference components mixed in the mixed signal Sₘᵢₓ(t), and Nᵢ(t) represents inherent white noise;
outputting the total common-mode output Sₚ(t) from the preamplifier (PreAMP); an expression of the total common-mode output Sₚ(t) is: Sₚ(t)=S_{c}(t)+N_{C} (t), wherein S_{C}(t) represents the common-mode interference components output from the preamplifier, and N_{C} (t) represents white noise mixed with the common-mode interference components S_{C}(t);
wherein the common-mode interference components S_{c}(t) mixed in the differential signal and the common-mode interference components S_{C}(t) are originated from the same interference sources, the common-mode interference components S_{C}(t) and the common-mode interference components S_{c}(t) satisfy a linear relationship expressed as:
$${S}_{c} t = k * {S}_{C} ( t ) ;$$
wherein a coefficient k satisfies a condition of Sᵢ=Minimizing_{k→}Var{Sₘᵢₓ(t)−k·Sₚ(t)}; this mathematical optimization variance expression implies that the total interference component S_{c}(t) in the differential signal is a proportionally scaled common-mode interference components S_{C}(t); since S_{C}(t)>S_{c}(t), k is typically less than 1;
the step of outputting both differential signal and common mode signal from the preamplifier (PreAMP) further comprises:
determining the coefficient k based on the condition of Sᵢ=Minimizing_{k→}Var{Sₘᵢₓ(t)−k·Sₚ(t)}, and using the coefficient k to determine the total common-mode interference component S_{c}(t) mixed in the differential signal, wherein the common-mode interference components Sₚ(t) serves as the interference noise template.

3. The general method according to claim 2, wherein the step of removing the common-mode interference components from the differential signal specifically comprises:
identifying the common-mode interference components S_{c}(t) corresponding to the total common-mode output Sₚ(t) in the mixed signal Sₘᵢₓ(t) and removing the common-mode interference components S_{c}(t) from the mixed signal Sₘᵢₓ(t) to obtain the original desired signal.

4. The general method according to claim 1, further comprising:
filtering and amplifying the differential signal transmitted in a signal channel, converting the differential mode signal into a first digital signal, and storing the first digital signal in a first memory or outputting the digital signal to a first MCU, to analyze and process the digital signal through the first MCU;
applying the same filtering and amplification treatment to the common-mode signal transmitted in the common-mode channel, converting the common-mode signal into a second digital signal, and storing the second digital signal in a second memory or outputting the second digital signal to a second MCU, to analyze and process the digital signal through the second MCU.
